(19) United States
(12) Patent Application Publication
(10) Pub. No.: US 2026/0041002 A1
(43) Pub. Date: Feb. 5, 2026

(54) SEMICONDUCTOR PACKAGE

(71) Applicant: SAMSUNG ELECTRONICS CO., LTD., SUWON-SI (KR)

(72) Inventor: HYUNSOO CHUNG, SUWON-SI (KR)

(21) Appl. No.: 19/060,830

(22) Filed: Feb. 24, 2025

(30) Foreign Application Priority Data
Jul. 31, 2024 (KR) 10-2024-0102051

(51) Int. Cl. H01L 25/16; H01L 23/00; H01L 23/31; H01L 23/367; H01L 23/373; H01L 23/42; H01L 23/48; H10B 80/00; H10D 80/30

(52) U.S. Cl. CPC H01L 25/16; H01L 23/3128; H01L 23/3672; H01L 23/42; H01L 23/481; H01L 24/08; H10B 80/00; H10D 80/30; H01L 23/3157; H01L 23/3736; H01L 24/16; H01L 24/96; H01L 24/97; H01L 2224/08145; H01L 2224/08225; H01L 2224/16227; H01L 2224/16238; H01L 2224/96; H01L 2224/97; H01L 2225/06513; H01L 2225/06544; H01L 2225/06589; H01L 2924/1431

(57) ABSTRACT

Provided is a semiconductor package including a package substrate, a first semiconductor device arranged on the package substrate, a second semiconductor device arranged on the first semiconductor device, a heat dissipation structure arranged on the second semiconductor device, and at least one first chip stack including a plurality of first core chips apart from the first semiconductor device in a lateral direction and sequentially stacked on the package substrate and a first buffer chip arranged on the second semiconductor device and the plurality of first core chips, wherein the heat dissipation structure is arranged apart from the first buffer chip in the lateral direction, and the plurality of first core chips include a plurality of first core through electrodes configured to penetrate at least a portion of each of the plurality of first core chips.

### CROSS-REFERENCE TO RELATED APPLICATION

This application claims priority under 35 U.S.C. § 119 to Korean Patent Application No. 10-2024-0102051, filed on Jul. 31, 2024 in the Korean Intellectual Property office, the disclosure of which is incorporated by reference herein in its entirety.

### FIELD

The present disclosure relates to a semiconductor package, and more particularly, to a semiconductor package including a plurality of stacked semiconductor chips.

### INTRODUCTION

As the demand for portable devices has rapidly increased in the electronics market, miniaturization and weight reduction of the electronic components used in the electronic devices have been sought. For miniaturization and weight reduction of some electronic components, the semiconductor packages mounted thereon are small in volume while capable of processing large amounts of data. Accordingly, semiconductor packages including a plurality of semiconductor chips have been developed. For example, several types of semiconductor chips may be mounted side by side on a package substrate, or semiconductor chips or packages may be stacked on a package substrate. There is continuous demand for a semiconductor package including stacked memory chips and logic chips.

### SUMMARY

The present disclosure describes a semiconductor package, including stacked memory chips and logic chips, having high heat dissipation characteristics, speed, and quality of signal transmission.

Embodiments of the present disclosure are not limited to those mentioned herein, and others may be clearly understood by those of ordinary skill in the pertinent art based on the following description.

According to an embodiment of the present disclosure, there is provided a semiconductor package including a package substrate, a first semiconductor device arranged on the package substrate, a second semiconductor device arranged on the first semiconductor device, a heat dissipation structure arranged on the second semiconductor device, and at least one first chip stack including a plurality of first core chips and a first buffer chip, wherein the plurality of first core chips are apart from the first semiconductor device in a lateral direction and sequentially stacked on the package substrate, wherein the first buffer chip is arranged on the second semiconductor device and the at least one first chip stack, wherein the heat dissipation structure is arranged apart from the first buffer chip in a lateral direction, and wherein the plurality of first core chips include a plurality of first core through electrodes configured to penetrate at least a portion of each of the plurality of first core chips.

According to an embodiment of the present disclosure, there is provided a semiconductor package including a package substrate, a first semiconductor device arranged on the package substrate and including a memory chip, a second semiconductor device arranged on the first semiconductor device and including a logic chip, a heat dissipation structure arranged on the second semiconductor device, at least one first chip stack including a plurality of first core chips and a first buffer chip, wherein the plurality of first core chips are apart from the first semiconductor device in a lateral direction and sequentially stacked on the package substrate, and the first buffer chip is arranged on the second semiconductor device and the plurality of first core chips, and a package encapsulation member surrounding the at least one first chip stack, the first semiconductor device, the second semiconductor device, and the heat dissipation structure, wherein the heat dissipation structure is arranged apart from the first buffer chip in a lateral direction, wherein the plurality of first core chips include a plurality of first core through electrodes configured to penetrate at least a portion of each of the plurality of first core chips, the first semiconductor device includes a plurality of first through electrodes, and the second semiconductor device includes a plurality of second through electrodes, wherein a portion of the first buffer chip overlaps a portion of the second semiconductor device in a vertical direction, and wherein an upper surface of the first buffer chip, an upper surface of the heat dissipation structure, and an upper surface of the package encapsulation member are coplanar with each other.

According to an embodiment of the present disclosure, there is provided a semiconductor package including a package substrate, a first semiconductor device arranged on the package substrate and including a memory chip, a second semiconductor device arranged on the first semiconductor device and including a logic chip, a heat dissipation structure arranged on the second semiconductor device, at least one first chip stack including a plurality of first core chips and a first buffer chip, wherein the plurality of first core chips are apart from the first semiconductor device in a lateral direction and sequentially stacked on the package substrate, and the first buffer chip is arranged on the second semiconductor device and the plurality of first core chips, and a package encapsulation member surrounding the at least one first chip stack, the first semiconductor device, the second semiconductor device, and the heat dissipation structure, wherein the heat dissipation structure is arranged apart from the first buffer chip in a lateral direction, wherein the plurality of first core chips include a plurality of first core through electrodes configured to penetrate at least a portion of each of the plurality of first core chips, the first semiconductor device includes a plurality of first through electrodes, and the second semiconductor device includes a plurality of second through electrodes, wherein a portion of the first buffer chip overlaps a portion of the second semiconductor device in a vertical direction, wherein an upper surface of the first buffer chip, an upper surface of the heat dissipation structure, and an upper surface of the package encapsulation member are coplanar with each other, wherein the first buffer chip includes a first physical layer, wherein the second semiconductor device includes a second physical layer, wherein the first physical layer is arranged closer to a first side surface of the first buffer chip than a second side surface of the first buffer chip, wherein the second physical layer is arranged closer to a third side surface of the second semiconductor device than a fourth side surface of the second semiconductor device, wherein the first side surface of the first buffer chip faces the heat dissipation structure, the second side surface is a surface opposite to the first side surface, the fourth side surface is a surface opposite to the third side surface, and the third side surface faces side surfaces of the plurality of first core chips, wherein a vertical level of an upper surface of the second semiconductor device is substantially the same as or potentially identical to a vertical level of an upper surface of an uppermost first core chip farthest apart from the package substrate among the plurality of first core chips, wherein the first semiconductor device includes a first semiconductor chip, the plurality of first through electrodes configured to penetrate at least a portion of the first semiconductor chip, a first encapsulation member surrounding the first semiconductor chip, and a first redistribution structure facing the first semiconductor chip, wherein the plurality of first through electrodes are electrically connected to the first redistribution structure, the first semiconductor chip includes a first active surface, and the first active surface is provided closer to an upper surface of the first semiconductor chip than a lower surface of the first semiconductor chip, and wherein the second semiconductor device includes a second semiconductor chip, a plurality of second through electrodes configured to penetrate at least a portion of the second semiconductor chip, and a second redistribution structure arranged on one surface of the second semiconductor chip and electrically connected to the plurality of second through electrodes.

### BRIEF DESCRIPTION OF THE DRAWINGS

Embodiments will be more clearly understood from the following detailed description taken in conjunction with the accompanying drawings, in which:

FIG. 1 is a section diagram showing a front cross-sectional view of a semiconductor package according to an embodiment;

FIG. 2 is a section diagram showing a front cross-sectional view of a semiconductor package according to an embodiment;

FIG. 3 is a section diagram showing a front cross-sectional view of a semiconductor package according to an embodiment;

FIG. 4 is a section diagram showing a front cross-sectional view of a semiconductor package according to an embodiment;

FIGS. 5A through 5H are section diagrams showing front cross-sectional views sequentially illustrating a process of manufacturing a semiconductor package, according to an embodiment; and

FIGS. 6A through 6E are section diagrams showing front cross-sectional views sequentially illustrating a process of manufacturing a semiconductor package, according to an embodiment.

### DETAILED DESCRIPTION

Hereinafter, one or more illustrative embodiments may be described in detail with reference to the accompanying drawings.

Embodiments are provided to more fully describe the technical ideas of the inventive concept to those of ordinary skill in the pertinent art, who may readily recognize that each embodiment as set forth below may be modified in various ways, and that the scope of the inventive concept is not limited thereto. Rather, each embodiment is provided to describe an illustrative example of the inventive concept more faithfully and completely by way of non-limiting examples, and to fully convey the idea of the technical ideas therein to those skilled in the art. In addition, the thickness and/or size of each layer in the drawings may be exaggerated for ease of explanation.

In the description that follows, a first direction may mean the X direction, a second direction may mean the Y direction, and the first direction may be perpendicular to the second direction. A third direction may mean the Z direction, and the third direction may be perpendicular to both the first direction and the second direction. A horizontal plane or a planar surface may be referred to as an X-Y plane. The upper surface of an object may mean one surface located in a positive third direction with respect to the object, and the lower surface of the object may mean one surface located in a negative third direction with respect to the object.

In an embodiment, a number of high-bandwidth memories (HBMs) or core memory chips may be stacked on a package substrate, and a three-dimensional integrated circuit (3D-IC), such as a stack of semiconductor devices, may be disposed in a lateral direction next to the stacked HBMs. The 3D-IC may have substantially the same height as the stacked HBMs. The 3D-IC may include a first semiconductor device having a relatively lower heat generating chip such as a memory chip, which may be arranged under a second semiconductor device having a relatively higher heat generating chip such as a logic chip. A buffer chip may overlap at least a portion of the 3D-IC and at least a portion of the stacked HBMs.

The buffer chip and the second semiconductor device, which may generate relatively more heat than the other elements, may be arranged farther from the package substrate. Moreover, a heat dissipation structure may be attached to the top of the second semiconductor device. An upper surface of the buffer chip and an upper surface of the heat dissipation structure may be disposed at an upper surface of a package encapsulation member, and heat dissipation of a component generating relatively more heat than others may be optimized. In addition, because signal transfer with the second semiconductor device may be performed via the buffer chip rather than through a separate interposer, quality and speed of signal transfer may be maximized.

A portion of the buffer chip may extend from the top of the stacked HBMs onto the top of the second semiconductor device, overlapping both in a vertical direction. In addition, the vertical level or height of an upper surface of the stacked HBMs or core memory chips may have substantially the same vertical level or height as an upper surface of the second semiconductor device, and the buffer chip may be co-planar with both. Moreover, the heat dissipation structure may have substantially the same vertical level or height as the buffer chip.

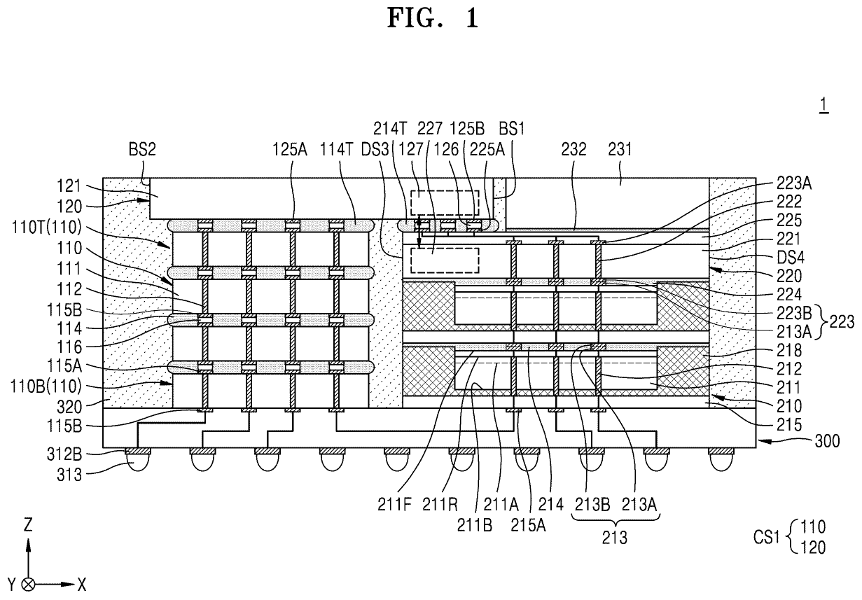

FIG. 1 shows a cross-sectional view of a semiconductor package 1 according to an embodiment.

Referring to FIG. 1, the semiconductor package 1 may include a package substrate 300, a first chip stack CS1 arranged on the package substrate 300, a first semiconductor device 210 arranged in a lateral direction from the first chip stack CS1 on the package substrate 300, a second semiconductor device 220 arranged on the first semiconductor device 210, a heat dissipation structure 231 arranged on the first semiconductor device 210, and a package encapsulating member 320 surrounding the first chip stack CS1, the first semiconductor device 210, the second semiconductor device 220, and the heat dissipation structure 231.

The first chip stack CS1 may include a plurality of first core chips 110 and a first buffer chip 120. The plurality of first core chips 110 may include two or more first core chips 110. For example, the plurality of first core chips 110 may include four first core chips 110. Alternatively, the plurality of first core chips 110 may include two, six, or eight first core chips 110, without limitation. Although FIG. 1 describes an example in which the plurality of first core chips 110 include four first core chips 110, the number of first core chips 110 included in the plurality of first core chips 110 is not limited thereto.

Each first core chip 110 may include a first core substrate 111. The first core substrate 111 may include, for example, silicon (Si). Alternatively, the first core substrate 111 may include a semiconductor element such as germanium (Ge), or a compound semiconductor, such as silicon carbide (SiC), gallium arsenide (GaAs), indium arsenide (InAs), and/or indium phosphide (InP). Alternatively, the first core substrate 111 may have a silicon-on-insulator (SOI) structure. For example, the first core substrate 111 may include a buried oxide (BOX) layer. The first core substrate 111 may include a conductive region. For example, a conductive region may include a well doped with impurities. The first core substrate 111 may have various device separation structures, such as a shallow trench isolation (STI) structure. The first core substrate 111 may include a first core active surface and a first core inactive surface opposite to the first core active surface. The first core active surface may be referred to as a first core substrate front surface, and the first core inactive surface may be referred to as a first core substrate rear surface.

In each first core chip 110, a semiconductor device including a plurality of individual devices of various types may be formed on the first core active surface. The plurality of individual devices may include various microelectronic devices, for example, a metal-oxide-semiconductor field effect transistor (MOSFET) such as a complementary metal-oxide-semiconductor (CMOS) transistor, an image sensor such as a floating gate transistor, a system large scale integration (LSI) device, a CMOS imaging sensor (CIS), a micro-electro-mechanical system (MEMS), an active device, a passive device, or the like.

The plurality of individual devices may be electrically connected to the conductive area of the first core substrate 111. In addition, each of the plurality of individual devices may be electrically isolated from adjacent individual devices by an insulating layer.

For example, each first core chip 110 may include a memory semiconductor chip. In an embodiment, the memory semiconductor device may include random-access memory (RAM). In an embodiment, the memory semiconductor device may include a volatile memory semiconductor technology or chip such as dynamic random-access memory (DRAM). In an embodiment, the memory semiconductor device may include a non-volatile memory semiconductor device, such as flash memory, phase change RAM (PRAM), magnetic RAM (MRAM), ferroelectric RAM (FeRAM), and/or resistive RAM (RRAM). The flash memory may include, for example, a three-dimensional (3D) technology such as V-NAND® flash memory.

Each first core chip 110 may include a first core substrate 111 having a first core substrate front surface and a first core substrate rear surface. One surface adjacent to the first core active surface of the first core chip 110 may be referred to as the first core substrate front surface, and one surface opposite to the first core substrate front surface may be referred to as the first core substrate rear surface. In an embodiment, one surface facing upward with respect to the vertical direction may be referred to as an upper surface, and one surface facing downward with respect to the vertical direction may be referred to as a lower surface. For example, an upper surface of the first core chip 110 may be a front surface of the first core substrate, and a lower surface of the first core chip 110 may be a rear surface of the first core substrate. The first core chip may be arranged on the package substrate 300 such that the first core active surface of the first core chip 110 is located farther from the package substrate 300 than the first core substrate rear surface which may be the first core inactive surface.

The plurality of first core chips 110 may include a lowermost first core chip 110B positioned closest to the package substrate 300 among the plurality of first core chips 110, and an uppermost first core chip 110T positioned farthest from the package substrate 300 among the plurality of first core chips 110. The uppermost and/or lowermost first core chips may differ from any intervening first core chips. For example, the lowermost first core chip 110B may include a different first lower chip pad 113B or 115B.

The plurality of first core chips 110 may include a memory semiconductor chip. According to an embodiment, a first core chip 110 may include a memory chip including memory cells. According to an embodiment, the first buffer chip 120 may include a semiconductor substrate 121 having a serial-parallel conversion circuit for parallelizing a data signal received from a controller chip and transmitting the parallelized data signal to a memory chip, and the serial-parallel conversion circuit may be for control of the plurality of first core chips 110. The first buffer chip 120 may also be referred to as an interface die, a base die, a logic die, a master die, or the like.

A buffer chip front surface of the first buffer chip on which the active surface of the first buffer chip 120 is provided may face downward. For example, the buffer chip front surface of the first buffer chip 120 may face the first core chip 110. Because a lower surface of the first buffer chip 120 faces the uppermost first core chip 110T and the second semiconductor device 220, the buffer chip front surface, including the active surface of the first buffer chip 120, may be arranged to face an upper surface of the uppermost first core chip 110T and an upper surface of the second semiconductor device 220.

For example, the first chip stack CS1 including the plurality of first core chips 110 and the first buffer chip 120 may include a high bandwidth memory (HBM). The first buffer chip 120 may therefore be referred to as an HBM controller die, and the plurality of first core chips 110 may be referred to as a DRAM die.

The first buffer chip 120 may include a first interface physical area PHY 127. The first interface PHY 127 may be arranged in some area of the first buffer chip 120. The first interface PHY 127 may be for transmitting data, and may physically connect devices and serve as the conduit that encodes and/or decodes bits of data. For example, the first interface PHY 127 of the first buffer chip 120 may transceive data between the plurality of first core chips 110 and a second semiconductor substrate 221 of the second semiconductor device 220 as set forth below.

The first interface PHY 127 of the first buffer chip 120 may be provided adjacent to one side surface of the first buffer chip 120 on the first buffer chip 120. For example, the first interface PHY 127 may be provided more adjacent or closer to a first side surface BS1 than a second side surface BS2 of the first buffer chip 120. For example, the first interface PHY 127 may be provided at a position in the first buffer chip 120 that is adjacent to the second semiconductor device 220. Alternatively, the first interface PHY 127 may be provided adjacent to a portion of the first buffer chip 120 that protrudes in a lateral direction from the first core chip 110.

A plurality of first through electrodes 112 may be disposed in through-silicon vias (TSVs). A first through electrode 112 may include a conductive plug penetrating at least a portion of the first core substrate 111 and a conductive barrier layer surrounding the conductive plug. A via insulating layer may be arranged between the first through electrode 112 and the first core substrate 111, and surround sidewalls of the first through electrode 112. The first through electrode 112 may be formed in any one of a via-first structure where the via hole is formed first before placement of components or bonding dice on top of an interposer, a via-middle structure where the via hole is placed after placement of circuitry and before metallization, and/or a via-last structure where the via hole is formed after stacking and metallization.

A plurality of first upper chip pads 115A may be provided on the upper surface of each first core chip 110. A plurality of first lower chip pads 115B may be provided under the lower surface of each first core chip 110. A first chip connection terminal 116 may be provided between each of the plurality of first upper chip pads 115A and each of the plurality of first lower chip pads 115B adjacent thereto. The plurality of first core chips 110 may be electrically connected to each other via the first upper chip pad 115A, the first lower chip pad 115B, and the first chip connection terminal 116.

A first buffer chip pad 125A and a second buffer chip pad 125B may be provided under the lower surface of the first buffer chip 120. A third inter-chip molding material 114T may be provided between the buffer chip and the uppermost first core chip 110T, and a fourth inter-chip molding material 214T may be provided between the buffer chip and the second semiconductor device 220. The materials 114T and 214T may be the same or different from each other, and need not be the same as the first inter-chip molding material 114 nor a second inter-chip molding material 214. The inter-chip molding materials 114T and/or 214T may include a non-conductive film (NCF) or a non-conductive paste (NCP), without limitation thereto.

The first chip connection terminal 116 may be provided between the first buffer chip pad 125A and the first upper chip pad 115A provided on the upper surface of the uppermost first core chip 110T. The first buffer chip pad 125A may be electrically connected to the first upper chip pad 115A on the upper surface of the uppermost first core chip 110T via the first chip connection terminal 116. For example, the first chip connection terminal 116 may include a solder ball, a bump, a wire bond, or the like.

The first buffer chip 120 may include the first side surface BS1 of the first buffer chip 120 facing the heat dissipation structure 231 as set forth below, and the second side surface BS2 of the first buffer chip 120, which is a surface opposite to the first side surface BS1 of the first buffer chip 120. The first side surface BS1 of the first buffer chip 120 may face a side surface of the heat dissipation structure 231 provided on the second semiconductor device 220 as set forth below. The first buffer chip pad 125A may be closer to the second side surface BS2 of the first buffer chip 120 than the second buffer chip pad 125B, and the second buffer chip pad 125B may be closer to the first side surface BS1 of the first buffer chip 120 than the first buffer chip pad 125A. As set forth below, the second buffer chip pad 125B may be electrically connected to the second semiconductor device 220.

An inter-chip molding material 114 may be provided between each of the first core chip 110, the lowermost first core chip 110B, and the plurality of first core chips 110. The inter-chip molding material 114 may include a non-conductive film (NCF) or a non-conductive paste (NCP). As illustrated, the inter-chip molding materials 114 may be distinguished from each other. Alternatively, the inter-chip molding materials 114 may extend from the side surfaces of the first core chip 110, be attached to each other, and thus need not be distinguished from each other.

A portion of the first buffer chip 120 may overlap a portion of the second semiconductor device 220 in a vertical direction. A distance to which the first side surface BS1 of the first buffer chip 120 protrudes from the uppermost first core chip 110T may be greater than a distance to which the second side surface BS2 of the first buffer chip 120 protrudes from the uppermost first core chip 110T. As a portion of the first buffer chip 120 overlaps a portion of the second semiconductor device 220 in a vertical direction, the second buffer chip pad 125B provided under the lower surface of the first buffer chip 120 may be electrically connected to a second upper surface connection pad 225A provided in the second semiconductor device 220.

A second chip connection terminal 126 may be provided between the second upper surface connection pad 225A, on the upper surface of the second semiconductor device 220, and the second buffer chip pad 125B provided under the lower surface of the first buffer chip 120. For example, the first buffer chip 120 may be electrically connected to the second semiconductor device 220 via the second upper surface connection pad 225A provided on the upper surface of the second semiconductor device 220, the second buffer chip pad 125B provided under the lower surface of the first buffer chip 120, and the second chip connection terminal 126. The inter-chip molding material 114, 114T, 214 and/or 214T may surround the second chip connection terminal 126, and be provided between the first buffer chip 120 and the second semiconductor device 220.

A vertical level of an upper surface of the uppermost first core chip 110T, of the plurality of first core chips 110, with respect to an upper surface of the package substrate 300, and a vertical level of the upper surface of the second semiconductor device 220, with respect to the upper surface of the package substrate 300, may be substantially the same, and the first buffer chip 120 may be simultaneously mounted on the plurality of first core chips 110 and the second semiconductor device 220.

One or more first semiconductor devices 210 may be provided on the package substrate 300. For example, as illustrated in FIG. 1, two first semiconductor devices 210 may be vertically stacked one on top of the other and provided on the package substrate 300. In addition, the second semiconductor device 220 may be stacked and provided on the first semiconductor devices 210.

Each first semiconductor device 210 may include a first semiconductor substrate 211, the plurality of first through electrodes 212 penetrating at least a portion of the first semiconductor substrate 211, a first bonding insulating layer 224 provided on an upper surface of the first semiconductor substrate 211, a first bonding pad 213, and a first redistribution layer 215 facing a lower surface of the first semiconductor substrate 211.

Each first semiconductor substrate 211 may include a first active surface 211A, a first semiconductor structure formed on the first active surface 211A of the first semiconductor substrate 211, and a first wiring structure layer 221R arranged on the first active surface 211A.

The first semiconductor substrate 211 may include a first substrate front surface 211F and a first substrate rear surface 211B. One surface of the first semiconductor substrate 211 adjacent to the first active surface 211A may be referred to as the first substrate front surface 211F, and one surface opposite to the first substrate front surface 211F may be referred to as the first substrate rear surface 211B. The upper surface of the first semiconductor substrate 211 may include the first substrate front surface 211F, and the lower surface of the first semiconductor substrate 211 may include the first substrate rear surface 211B. The first semiconductor substrate 211 may be arranged inside the first semiconductor device 210, and the first active surface 211A of the first semiconductor substrate 211 may be farther from the package substrate 300 than the first substrate rear surface 211B.

For example, the first semiconductor substrate 211 included in the first semiconductor device 210 may include a memory semiconductor chip. In an embodiment, the memory semiconductor chip may include a volatile memory device, such as DRAM and/or static random-access memory (SRAM). In an embodiment, the memory semiconductor device may include a non-volatile memory semiconductor device, such as flash memory, phase change RAM (PRAM), magnetic RAM (MRAM), ferroelectric RAM (FeRAM), and resistive RAM (RRAM). The flash memory may include, for example, a V-NAND flash memory.

The first semiconductor substrate 211 may include, for example, a semiconductor material such as silicon (Si), germanium (Ge), or the like. Alternatively, the first semiconductor substrate 211 may include multiple semiconductor materials. The first semiconductor substrate 211 may include an active surface and an inactive surface opposite to the active surface. The first semiconductor substrate 211 may include a conductive area, for example, a well doped with impurities. The first semiconductor substrate 211 may have various device separation structures such as a shallow trench isolation (STI) structure.

The first semiconductor device formed on the first active surface 211A of the first semiconductor substrate 211 may include various types of individual devices. The plurality of individual devices may include various microelectronic devices, for example, a metal-oxide-semiconductor field effect transistor (MOSFET) such as a complementary metal-oxide-semiconductor (CMOS) transistor, an image sensor, such as a system large scale integration (LSI) sensor and a CMOS imaging sensor (CIS), a micro-electro-mechanical system (MEMS), an active device, a passive device, or the like. The plurality of individual devices may be electrically connected to the conductive area of the first semiconductor substrate 211 or the second semiconductor substrate 221. The first semiconductor device may further include a conductive wiring or a conductive plug electrically connecting at least two of the plurality of individual devices to each other, or the plurality of individual devices to the conductive area of the first semiconductor substrate 211. In addition, each of the plurality of individual devices may be electrically isolated from another adjacent individual device by an insulating layer.

The first wiring structure layer 211R may include a plurality of first wiring patterns, a plurality of first wiring vias each penetrating at least part way through the semiconductor substrate 211, and a first inter-wiring insulating layer. At least one of first wiring pattern of the plurality of first wiring patterns may be connected to at least one first wiring via of the plurality of first wiring vias. The plurality of first wiring patterns may extend in a horizontal direction (e.g., X direction, Y direction, or an X-Y direction), and the plurality of first wiring vias may extend in a vertical direction (e.g., Z direction). Some of the plurality of first wiring patterns and some others of the plurality of first wiring patterns may be arranged at different vertical levels, and thus, the plurality of first wiring patterns and the plurality of first wiring vias may have a multilayer wiring structure.

A first upper connection pad 213A provided on the first wiring structure layer 211R may be electrically connected to the first semiconductor device of the first active surface 211A provided on the first semiconductor substrate 211 via the first wiring structure layer 211R. A first lower connection pad 213B provided on the lower surface of the first semiconductor device 210 may be electrically connected to the first semiconductor device of the first active surface 211A of the first semiconductor substrate 211 via a first redistribution pattern included in the first redistribution layer 215 and the plurality of first through electrodes 212. In addition, the first lower connection pad 213B on the lower surface of the first semiconductor device 210 may be electrically connected to the first upper connection pad 213A on the first wiring structure layer 211R via the plurality of first through electrodes 212. A second inter-chip molding material 214 may be provided between each of the two first semiconductor devices 210, and/or between them and the second semiconductor device 220. The inter-chip molding material 214 may include a non-conductive film (NCF) or a non-conductive paste (NCP), without limitation thereto, and need not be the same as the first inter-chip molding material 114.

In an embodiment, a case in which two first semiconductor devices 210 are stacked and provided on the package substrate 300 is described as an example, but the number of first semiconductor devices 210 is not limited thereto.

The first upper connection pad 213A of the first semiconductor device 210 arranged on the upper surface of the package substrate 300 may be directly bonded to the first lower connection pad 213B of the first semiconductor device 210 arranged on the first upper connection pad 213A. The direct bonding of any two devices may include the direct bonding of conductive components at positions facing each other at an interface of the two devices, and the direct bonding of insulating components at positions facing each other of the two devices. The direct bonding of the insulating components may include forming a chemical bond between the insulating components, without limitation thereto. The direct bonding of any two devices may include a hybrid bonding.

During a direct bonding process, metal atoms inside the first upper connection pad 213A of the first semiconductor device 210 may diffuse into the first lower connection pad 213B of the first semiconductor device 210, and/or metal atoms inside the first lower connection pad 213B may diffuse into the first upper connection pad 213A. Accordingly, an interface between the first upper connection pad 213A and the first lower connection pad 213B of the first semiconductor device 210 need not be distinguished. Thus, the first upper connection pad 213A may be firmly bonded to the first lower connection pad 213B.

In FIG. 1, a dashed line, which is depicted for distinguishing the first upper connection pad 213A from the first lower connection pad 213B prior to bonding, may indicate a virtual interface. The first upper connection pad 213A and the first lower connection pad 213B integrated by the direct bonding process in this manner may be collectively referred to as the first bonding pad 213. For example, the first bonding pad 213 may include a material including copper (Cu). In an embodiment, the electrical connection between the first semiconductor device 210 and the other first semiconductor device 210 need not be a direct bonding, but may be made by a connection terminal provided between the first upper connection pad 213A and the first lower connection pad 213B.

A first lower insulating layer provided under a lower surface of the first semiconductor device 210, such as under the first redistribution layer 215, may be in direct contact with a first upper insulating layer provided on an upper surface of another adjacent first semiconductor device 210, and the first lower insulating layer provided under the lower surface of the first semiconductor device 210 may be connected to the first upper insulating layer provided on the upper surface of another adjacent semiconductor device 210 by using direct bonding, without limitation thereto.

For example, a chemical bonding may be provided between the first lower insulating layer provided under the lower surface of the first semiconductor device 210 and the first upper insulating layer provided on the upper surface of another adjacent first semiconductor device 210, and the chemical bonding may include a covalent bonding. An interface between the first upper insulating layer and the first lower insulating layer need not be distinguished. In an embodiment, the first upper insulating layer and the first lower insulating layer are illustrated without being distinguished, and the first upper insulating layer and the first lower insulating layer may be collectively referred to as a first bonding insulating layer 224.

The first redistribution layer 215 of the first semiconductor device 210 may be electrically connected to a first lower connection pad 215A provided under a lower surface of the first redistribution layer 215 of the first semiconductor device 210, the power pad 215A may be recessed in the package substrate 300, and the first redistribution pattern included in the first redistribution layer 215 may electrically connect the plurality of first through electrodes 212 to the package substrate 300.

The first redistribution layer 215 may be formed by using a first redistribution process. The first redistribution layer 215 may include a first redistribution insulating layer and a plurality of first redistribution patterns. The first redistribution insulating layer may surround the plurality of first redistribution patterns. In an embodiment, the first redistribution layer 215 may include a stacked plurality of first redistribution insulating layers. The first redistribution insulating layer may include, for example, a material layer including an organic compound. In an embodiment, at least one lower first redistribution insulating layer may include a material layer including an organic polymer material. In an embodiment, the first redistribution insulating layer may include photosensitive polyimide (PSPI). The first redistribution insulating layer may include photo imageable dielectric. The first redistribution insulating layer may include, for example, photo sensitive polymer. The photo sensitive polymer may include, for example, at least one of a photosensitive polyimide, polybenzoxazole (PSPBO), phenol-based polymer, and/or benzocyclobutene-based polymer.

The plurality of first redistribution patterns provided on the first redistribution layer 215 may include a plurality of first redistribution line patterns and a plurality of first redistribution via patterns. The plurality of first redistribution patterns may include a conductor (e.g., a metal). For example, the conductor may include a material such as silver (Ag), copper (Cu), gold (Au), aluminum (AI), zinc (Zn), nickel (Ni), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and/or ruthenium (Ru), or an alloy thereof, without limitation thereto.

The plurality of first redistribution line patterns may be arranged at least one of an upper surface and a lower surface of the first redistribution insulating layer. The plurality of first redistribution via patterns may penetrate the first redistribution insulating layer to be connected to a portion of the plurality of first redistribution line patterns. In an embodiment, a portion of the plurality of first redistribution via patterns may be formed in one body together with a portion of the plurality of first redistribution line patterns.

The first through electrode 212 may penetrate at least a portion of the first semiconductor substrate 211. For example, the first through electrode 212 may penetrate the first semiconductor substrate 211 to the first wiring structure layer 211R of the first semiconductor substrate 211. The first through electrode 212 may protrude from the first substrate rear surface 211B of the first semiconductor substrate 211. The first through electrode 212 protruding from the first substrate rear surface 211B may be connected to a first redistribution pattern provided in the first redistribution layer 215. In an embodiment, an electrical connection by the first redistribution pattern of the first redistribution layer 215 and a second redistribution layer 225 as set forth below is schematically illustrated and displayed as a dashed line.

A first encapsulating member 218 may surround the first semiconductor substrate 211, and surround the plurality of first through electrodes 212 protruding from the first semiconductor substrate 211. The first encapsulating member 218 may include an epoxy mold compound (EMC), and the first encapsulating member 218 may further include a filler.

The second semiconductor device 220 may be arranged on the first semiconductor device 210. For example, the second semiconductor device 220 may be arranged or stacked on the two stacked first semiconductor devices 210, while being apart from the plurality of first core chips 110 in a lateral direction. The second semiconductor device 220 may include the second semiconductor substrate 221, a plurality of second through electrodes 222 penetrating at least a portion of the second semiconductor substrate 221, and the second redistribution layer 225 provided on a surface of the second semiconductor substrate 221.

The second semiconductor substrate 221 may include a logic semiconductor chip and/or a memory semiconductor chip. The logic semiconductor chip may include a microprocessor such as a central processing unit (CPU), a controller, an application specific integrated circuit (ASIC), a system on chip (SoC) type of array processor (AP), or the like. The memory semiconductor chip may include a volatile memory, such as DRAM and/or SRAM, or a non-volatile memory such as flash memory. For example, one or more semiconductor chips performing each unit function may be included in the second semiconductor substrate 221, which is one semiconductor substrate.

Like the first semiconductor substrate 211, the second semiconductor substrate 221 may include, for example, a semiconductor material such as Si or Ge. Alternatively, the second semiconductor substrate 221 may include multiple semiconductor materials. Each of the first semiconductor substrates 211 may include an active surface and an inactive surface opposite to the active surface. The second semiconductor substrate 221 may include a conductive area, for example, a well doped with impurities. The second semiconductor substrate 221 may have various device isolation structures such as the STI structure. A second semiconductor device formed on a second active surface of the second semiconductor substrate 221 may include various types of individual devices.

The second semiconductor substrate 221 may include a second interface PHY 227. The second interface PHY 227 may be provided to be closer to a third side surface DS3 of the second semiconductor substrate 221 than a fourth side surface DS4 of the second semiconductor substrate 221. For example, the second interface PHY 227 may be provided in the second semiconductor substrate 221 adjacent to the first buffer chip 120. The third side surface DS3 may face the side surface of the first core chip 110, and the fourth side surface DS4 may be referred to as a surface opposite to the third side surface DS3.

In the semiconductor package 1 according to an embodiment, because the second semiconductor device 220 overlaps the first buffer chip 120 in the vertical direction, and at the same time the second semiconductor device 220 is adjacent to and electrically connected to the first buffer chip 120, direct signal transmission and reception between the second semiconductor device 220 and the first buffer chip 120 may be possible without using a mediator such as a separate interposer. In addition, because the first buffer chip 120 is electrically connected to the plurality of first core chips 110, an electrical connection between the plurality of first core chips 110 and the second semiconductor device 220 may be formed in a relatively short distance. Accordingly, the semiconductor package 1 according to an embodiment may improve the signal quality of the semiconductor package 1 by reducing the electrical signal transmission/reception distance between the first core chip 110 including a memory module and the second semiconductor device 220 including a logic chip. For example, the signal transmission speed and latency in the semiconductor package 1 may be improved.

In addition, in the semiconductor package 1 according to an embodiment, as the second semiconductor device 220 overlaps the first buffer chip 120 in the vertical direction, a portion of the first buffer chip 120 having a relatively large plan area compared to the first core chip 110 may overlap other components. Accordingly, the size of the overall plan area of the semiconductor package 1 may be reduced.

The second redistribution layer 225 of the second semiconductor device 220 may be electrically connected to a second upper connection pad 225A provided on an upper surface of the second redistribution layer 225 of the second semiconductor device 220, and a second redistribution pattern included in the second redistribution layer 225 may electrically connect the plurality of second through electrodes 222 to the first buffer chip 120. The second redistribution layer 225 may be formed by using a second redistribution process. The second redistribution layer 225 may include a second redistribution insulating layer and a plurality of second redistribution patterns. A detailed description of the second redistribution layer 225 may be substantially the same as the description of the first redistribution layer 215 but for structure as shown in the drawings, so substantially duplicate description may be omitted.

In FIG. 1, an electrical connection between a second upper substrate pad 223A and the second redistribution layer 225A provided at one end of the plurality of second through electrodes 222 is illustrated, but the electrical connection may also be made between the second semiconductor devices and the second upper connection pad 225A formed on the second semiconductor substrate 221 via the second redistribution layer 225.

A second lower connection pad 223B may be provided under a lower surface of the second semiconductor device 220. The second lower connection pad 223B may be directly bonded to the first upper connection pad 213A provided on the upper surface of the first semiconductor device 210 provided under the second semiconductor device 220. The second lower connection pad 223B and the first upper connection pad 213A may be integrated into one body by using a direct bonding process, and may be collectively referred to as a second bonding pad 223.

A second lower insulating layer provided under the lower surface of the second semiconductor device 220 may be in direct contact with the first upper insulating layer provided on the upper surface of an adjacent first semiconductor device 210, and the second lower insulating layer provided under the lower surface of the second semiconductor device 220 may be connected to the first upper insulating layer provided on the upper surface of an adjacent first semiconductor device 210 by using the direct bonding. In an embodiment, the second lower insulating layer and the first upper insulating layer are illustrated without distinction, and the second lower insulating layer and the first upper insulating layer may be collectively referred to as a second bonding insulating layer 224.

The heat dissipation structure 231 may be provided on the second semiconductor device 220. For example, the heat dissipation structure 231 may be arranged on the second redistribution layer 225 included in the second semiconductor device 220. The heat dissipation structure 231 may be arranged apart from the first buffer chip 120 in a lateral direction on the second semiconductor device 220, and one side surface of the heat dissipation structure 231 may face the first side surface BS1 of the first buffer chip 120. A heat transfer layer 232 may be disposed between the heat dissipation structure 231 and the second semiconductor device 220. Via the heat transfer layer 232, heat may be transferred from the second semiconductor device 220 to the heat dissipation structure 231, and the heat dissipation structure 231 may be attached to the second semiconductor device 220.

The heat dissipation structure 231 may include a semiconductor such as silicon, or may include a conductor such as a metal including at least one of Al, Cu, Ti, Ni, Fe, Co, Pd, Pt, Au, Pb, Ag, C, Sn, W, and Cr, or an alloy thereof.

The heat transfer layer 232 may include a thermal interface material (TIM). The heat transfer layer 232 may have a higher heat transfer rate than a general adhesive material. In general, the heat transfer layer 232 may have a structure in which fillers such as metal particles are dispersed in a polymer material. The TIM may include, for example, mineral oil, grease, gap filler putty, phase change gel, a phase change material pad, a particle filled epoxy, or the like.

An upper surface of the heat dissipation structure 231 may be coplanar with the upper surface of the first buffer chip 120. Alternatively, the upper surface of the heat dissipation structure 231, the upper surface of the first buffer chip 120, and an upper surface of the package encapsulating member 320 may all be coplanar with each other. The upper surface of the heat dissipation structure 231 may be exposed to the outside. In an embodiment, a heat sink or the like for smoothing heat dissipation may be arranged on the upper surface of the heat dissipation structure 231, the upper surface of the first buffer chip 120, and the upper surface of the package encapsulation member 320.

The package encapsulation member 320 may surround the first chip stack CS1, the first semiconductor device 210, the second semiconductor device 220, and the heat dissipation structure 231. The package encapsulation member 320 may include a molding member including an EMC, and may further include a filler.

In the semiconductor package 1 according to an embodiment, the second semiconductor device 220 including a logic chip may be arranged farther from the package substrate 300 than the first semiconductor device 210. In addition, the upper surface of the first buffer chip 120 may be arranged to be exposed to the outside from the package encapsulation member 320. The second semiconductor device 220 and the first buffer chip 120 may include components which generate a relatively large amount of heat in the semiconductor package 1. By arranging the heat dissipation structure 231 of which the upper surface is exposed to the outside on the second semiconductor device 220, and by arranging the upper surface of the first buffer chip 120 to be exposed to the outside from the package encapsulation member 320, the heat dissipation from the second semiconductor device 220 and the first buffer chip 120 to the outside may be smoothly performed.

The package substrate 300 may include the external connection pad 312B and an external connection terminal 313 provided under the external connection pad 312B under a lower surface of the package substrate 300. The package substrate 300 may be connected to external electronic devices, for example, a printed circuit board, or the like, via the external connection terminal 313. The package substrate 300 may include, for example, a fourth redistribution structure.

When the package substrate 300 has a fourth redistribution structure, the package substrate 300 may include a plurality of fourth redistribution insulating layers and a fourth redistribution pattern provided in the fourth redistribution insulating layer. The fourth redistribution pattern may include a plurality of fourth redistribution line patterns and a plurality of fourth redistribution via patterns. The plurality of fourth redistribution line patterns may be respectively arranged between the plurality of fourth redistribution insulating layers, and the plurality of fourth redistribution via patterns may penetrate the fourth redistribution insulating layer to connect between each of the plurality of fourth redistribution line patterns. The fourth redistribution pattern may be electrically connected to the first lower connection pad 215A provided under the lower surface of the first semiconductor device 210.

In an embodiment, the fourth redistribution insulating layer may include an insulating material, for example, a photo imageable dielectric (PID) resin. In this case, the fourth redistribution insulating layer may further include an inorganic filler. The fourth redistribution pattern may include a conductive material, for example, Cu, Al, Ag, Sn, Au, Ni, Pb, Ti, or an alloy thereof.

In an embodiment, the electrical connections between the first lower connection pad 215A provided under the lower surface of the first semiconductor device 210, the first lower chip pad 115B provided under a lower surface of the lowermost first core chip 110B, and the external connection pad 312B provided under a lower surface of the package substrate 300 are schematically illustrated by solid lines.

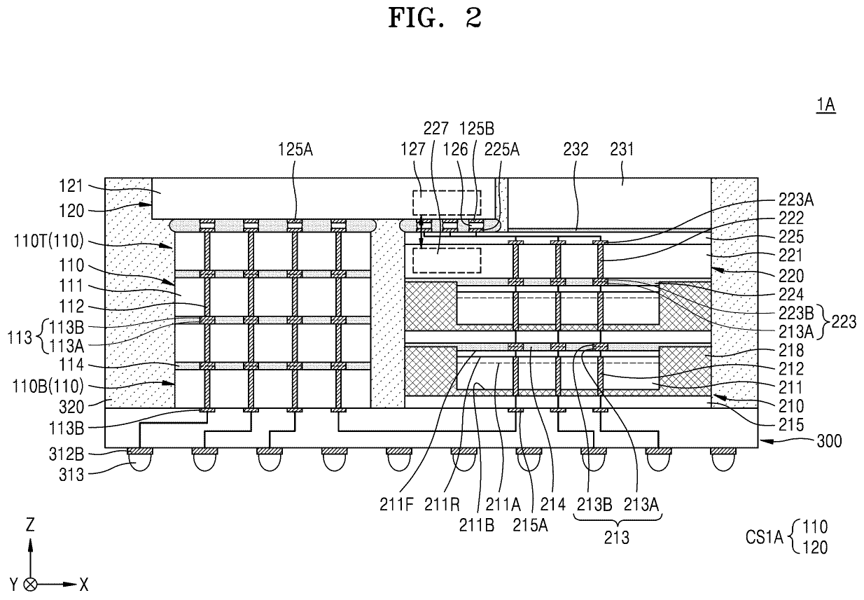

FIG. 2 shows a cross-sectional view of a semiconductor package 1A according to an embodiment. In the descriptions with respect to FIG. 2, descriptions not separately given may be substantially the same as the descriptions given above.

Referring to FIG. 2, the semiconductor package 1A may include the package substrate 300, a first chip stack CS1A arranged on the package substrate 300, the first semiconductor device 210 arranged from the first chip stack CS1A in a lateral direction on the package substrate 300, the second semiconductor device 220 arranged on the first semiconductor device 210, the heat dissipation structure 231 arranged on the first semiconductor device 210, and the package encapsulation member 320 surrounding the first chip stack CS1A, the first semiconductor device 210, the second semiconductor device 220, and the heat dissipation structure 231.

The first chip stack CS1A may include the plurality of first core chips 110 and the first buffer chip 120. The plurality of first core chips 110 may include two or more first core chips 110. A first upper chip pad 113A may be provided on the upper surface of each of the plurality of first core chips 110, and a first lower chip pad 113B may be provided under the lower surface of each of the plurality of first core chips 110. The first upper chip pad 113A and the first lower chip pad 113B provided between each of the plurality of first core chips 110 may be directly bonded to each other. For example, the first chip connection terminal 116 of the first chip stack CS1 of FIG. 1 may be omitted, which, in turn, may further reduce a stack height of the core chips. The first upper chip pad 113A and the first lower chip pad 113B may be integrated into one body by using the direct bonding process and may be collectively referred to as a first chip bonding pad 113.

The inter-chip molding material 114 surrounding the first chip bonding pad 113 and arranged between each of the plurality of first core chips 110 may be integrated into one body by using a direct contact and a direct connection of a first inter-chip insulating layer provided under the lower surface of the first core chip 110 to the first inter-chip insulating another adjacent first core chip 110.

The first buffer chip 120 may be electrically connected to the uppermost first core chip 110T by using a connection terminal without using a direct bonding to the uppermost first core chip 110T, but a method of connecting the first buffer chip 120 and the uppermost first core chip 110T is not limited thereto.

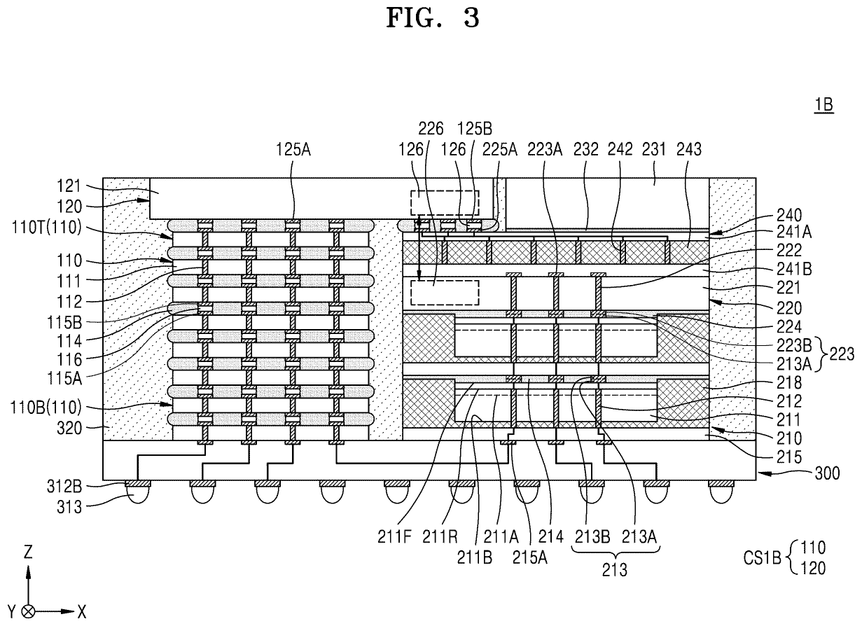

FIG. 3 shows a cross-sectional view of a semiconductor package 1B according to an embodiment. In the descriptions with respect to FIG. 3, descriptions not separately given may be substantially the same as the descriptions given above.

Referring to FIG. 3, the semiconductor package 1B may include the package substrate 300, a first chip stack CS1B arranged on the package substrate 300, the first semiconductor device 210 arranged apart from the first chip stack CS1B in a lateral direction on the package substrate 300, the second semiconductor device 220 arranged on the first semiconductor device 210, the heat dissipation structure 231 arranged on the first semiconductor device 210, and the package encapsulation member 320 surrounding the first chip stack CS1B, the first semiconductor device 210, the second semiconductor device 220, and the heat dissipation structure 231.

The first chip stack CS1B may include a plurality of first core chips 110 and the first buffer chip 120. The plurality of first core chips 110 may include two or more first core chips 110. For example, the plurality of first core chips 110 may include eight first core chips 110. FIG. 3 describes a case in which the plurality of first core chips 110 include eight first core chips 110 as an example, but the number of first core chips 110 included in the plurality of first core chips 110 is not limited thereto.

A filler structure 240 may be arranged on the second semiconductor device 220. Alternatively, the filler structure 240 may be arranged between the first semiconductor device 210 and another first semiconductor device 210.

The filler structure 240 may include an upper third redistribution layer 241A, a lower third redistribution layer 241B, a plurality of conductive fillers 242 vertically arranged between the upper third redistribution layer 241A and the lower third redistribution layer 241B, and a third encapsulation member 243 surrounding the plurality of conductive fillers 242 between the upper third redistribution layer 241A and the lower third redistribution layer 241B.

The upper third redistribution layer 241A may be electrically connected to the lower third redistribution layer 241B via a plurality of conductive fillers 242. The plurality of conductive fillers 242 may be electrically connected to the first buffer chip 120 via the upper third redistribution layer 241A. Because the second semiconductor device 220 may be electrically connected to the plurality of conductive fillers 242 via the lower third redistribution layer 241B, the second semiconductor device 220 may be electrically connected to the first buffer chip 120 by using the filler structure 240.

In the semiconductor package 1B according to an embodiment, the plurality of first core chips 110 may be provided in a first chip stack CS1B. FIG. 3 illustrates an example in which eight first core chips 110 are stacked, but for example, sixteen or more first core chips 110 may be stacked without limitation thereto. When the number of the first core chips 110 included in the stacked plurality of first core chips 110 increases, a vertical height of the plurality of first core chips 110 may be greater than a vertical height in which the first semiconductor device 210 and the second semiconductor device 220 are stacked.

When a vertical level of an upper surface of the uppermost first core chip 110T of the plurality of first core chips 110 is greater than a vertical level of the upper surface of the second semiconductor device 220, it may be difficult to connect the first buffer chip 120 simultaneously to the uppermost first core chip 110T and the second semiconductor device 220. Accordingly, by arranging the filler structure 240 on the second semiconductor device 220, and by configuring the vertical level of the uppermost first core chip 110T of the plurality of first core chips 110 to be substantially the same as a vertical level of an upper surface of the filler structure 240, the first buffer chip 120 may be simultaneously connected to the uppermost first core chip 110T and the filler structure 240. The semiconductor package 1B according to an embodiment may smoothly correspond to the vertical height of the stacked first core chips 110 by using the filler structure 240. Alternately, some of the first core chips 110 may be stacked underneath the lowermost first semiconductor device 210 to substantially equalize the stack heights. For example, at least one core chip may be stacked between the package substrate and the first semiconductor device.

However, in an embodiment, the filler structure 240 need not be arranged on the second semiconductor device 220, but may be arranged between the first semiconductor device 210 and another adjacent first semiconductor device 210, or between the first semiconductor device 210 and the second semiconductor device 220, or may be also arranged between the package substrate 300 and the first semiconductor device 210.

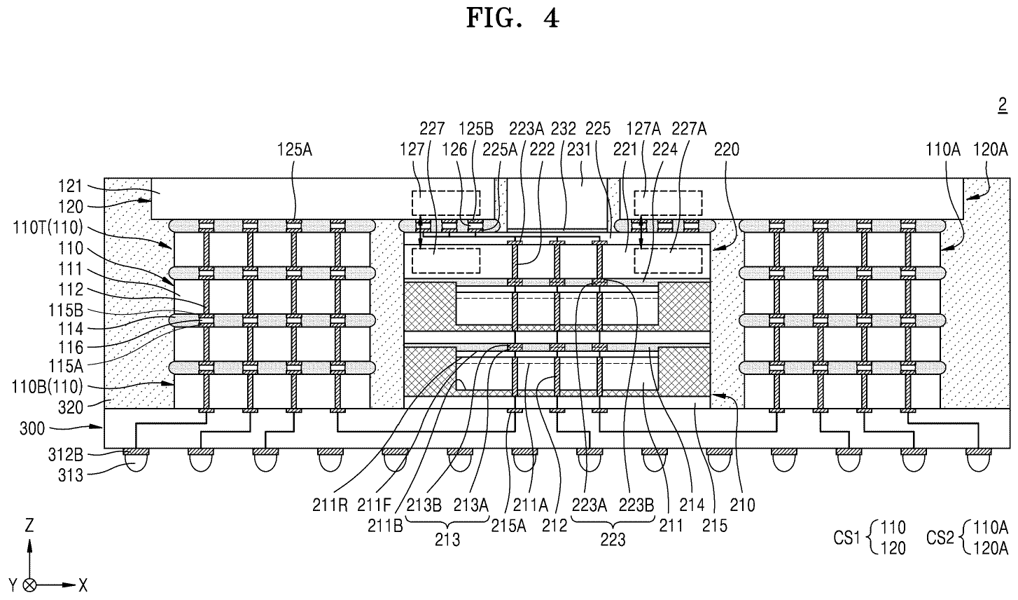

FIG. 4 shows a cross-sectional view of a semiconductor package 2 according to an embodiment. In the descriptions with respect to FIG. 4, descriptions not separately given may be substantially the same as the descriptions given above.

Referring to FIG. 4, the semiconductor package 2 may include the package substrate 300, the first chip stack CS1 arranged on the package substrate 300, the first semiconductor device 210 arranged apart from the first chip stack CS1 in a lateral direction on the package substrate 300, the second semiconductor device 220 arranged on the first semiconductor device 210, the heat dissipation structure 231 arranged on the first semiconductor device 210, and a second chip stack CS2 arranged opposite to the first chip stack CS1 with reference to the first semiconductor device 210, the second semiconductor device 220, the heat dissipation structure 231, and/or the package encapsulation member 320, which are arranged on the package substrate 300.

The second chip stack CS2 may include a plurality of second core chips 110A and a second buffer chip 120A. The plurality of second core chips 110A may include two or more second core chips 110A. The description of the second chip stack CS2 may be substantially the same as that of the first chip stack CS1. Substantially duplicate description may be omitted.

Based on the first chip stack CS1, the second chip stack CS2 may be provided on the opposite side of the first semiconductor device 210 and the second semiconductor device 220 on the package substrate 300. Like the first buffer chip 120 included in the first chip stack CS1, a portion of the second buffer chip 120A may overlap a portion of the second semiconductor device 220 in the vertical direction.

The second buffer chip 120A may include a first interface PHY 127A. The first interface PHY 127A may be arranged in some area of the second buffer chip 120A. The first interface PHY 127A may be for transmitting data, and for example, the first interface PHY 127 of the second buffer chip 120A may transceive data between the plurality of second core chips 110A and the second semiconductor substrate 221 of the second semiconductor device 220. The second semiconductor substrate 221 may include second interfaces PHY 227 and 227A. The second interface PHY 227A of the second semiconductor substrate 221 may be arranged relatively adjacent to the second buffer chip 120A in the second semiconductor substrate 221.

The heat dissipation structure 231 may be apart from the first buffer chip 120 in a lateral direction, and simultaneously apart from the second buffer chip 120A in the lateral direction to be arranged on the second semiconductor device 220. For example, the heat dissipation structure 231 may be provided between the first buffer chip 120 and the second buffer chip 120A. The heat transfer layer 232 may be arranged between the heat dissipation structure 231 and the second semiconductor device 220.

On the package substrate 300, the package encapsulation member 320 may surround the first chip stack CS1, the second chip stack CS2, the first semiconductor device 210, the second semiconductor device 220, and the heat dissipation structure 231. The upper surface of the heat dissipation structure 231, the upper surface of the first buffer chip 120, an upper surface of the second buffer chip 120A, and the upper surface of the package encapsulation member 320 may all be substantially coplanar with each other. The upper surface of the heat dissipation structure 231, the upper surface of the first buffer chip 120, and the upper surface of the second buffer chip 120A may be exposed to the outside.

The semiconductor package 2 according to an embodiment may include a plurality of chip stacks, Moreover, heat dissipation from the first buffer chip 120, the second buffer chip 120A, and the second semiconductor device 220 to the outside may be smoothly performed. In addition, by reducing the electrical signal transmission/reception distance between the first core chip 110 including the memory module and the first buffer chip 120, and the second semiconductor device 220 including the logic chip, the signal quality of the semiconductor package 2 may be improved, and the overall plan area size of the semiconductor package 2 may be reduced.

Although two core stacks have been described for illustrative purposes, embodiments are not limited thereto. For example, the semiconductor package may include six core stacks and six buffer chips arranged or tiled hexagonally around the stacked semiconductor devices 210 and 220. Moreover, multiple buffer chips may be integrally formed as one, with a relief in the center for the heat dissipation structure. In addition, the semiconductor devices 210 and 220 may have any shape in a horizontal plane, such as but not limited to a hexagonal shape.

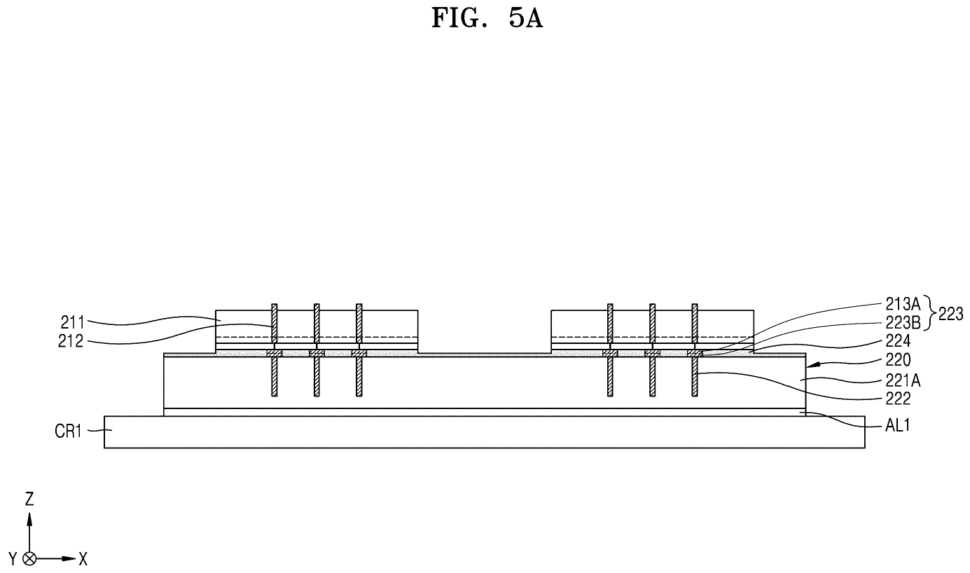

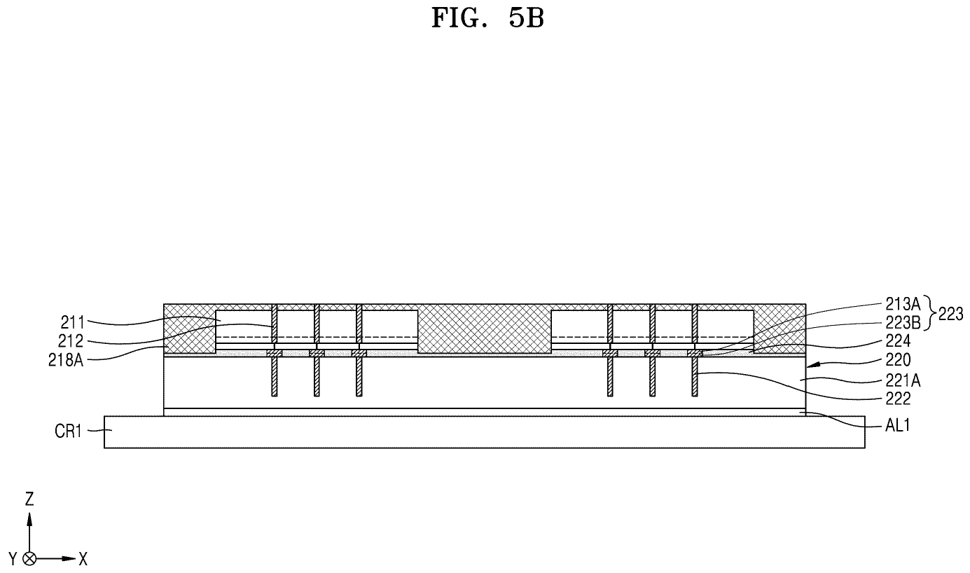

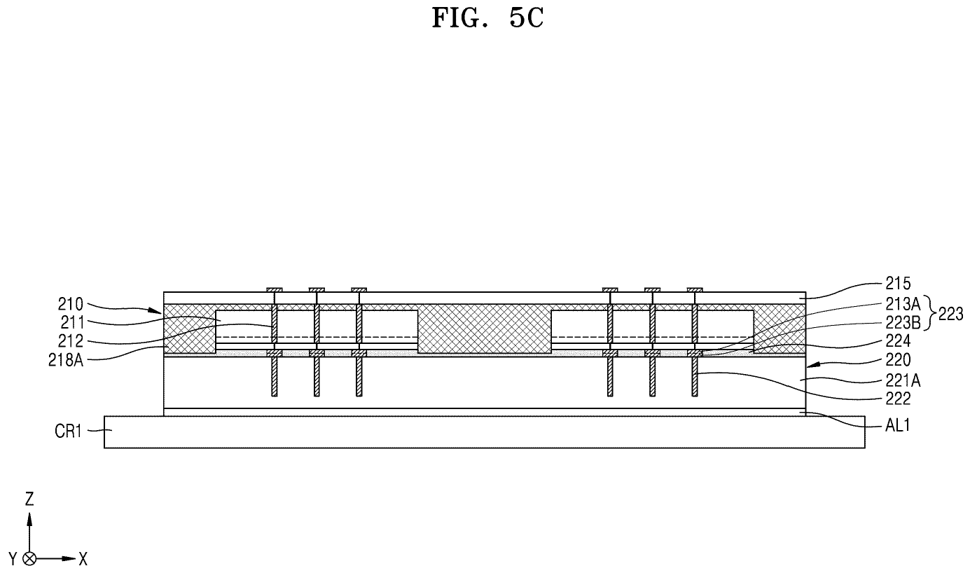

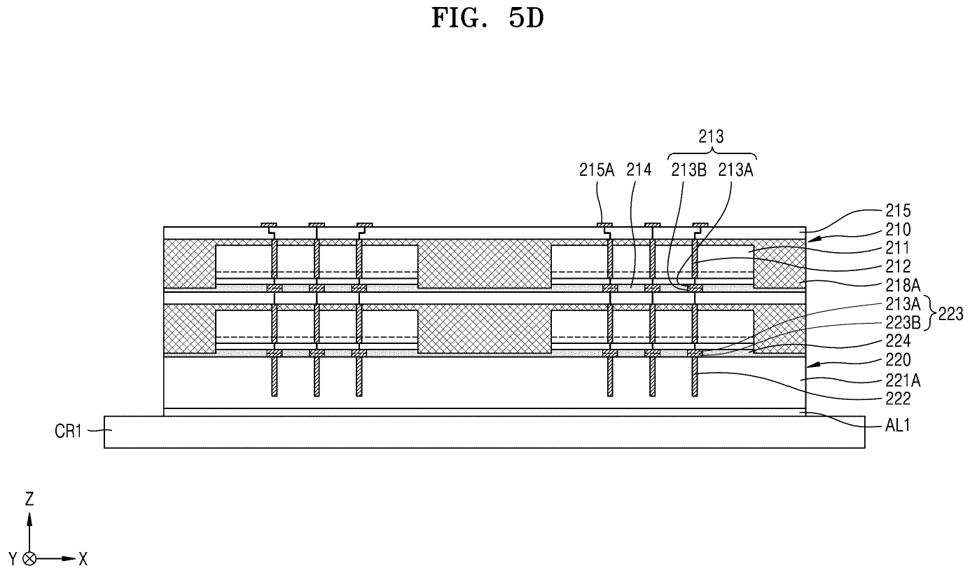

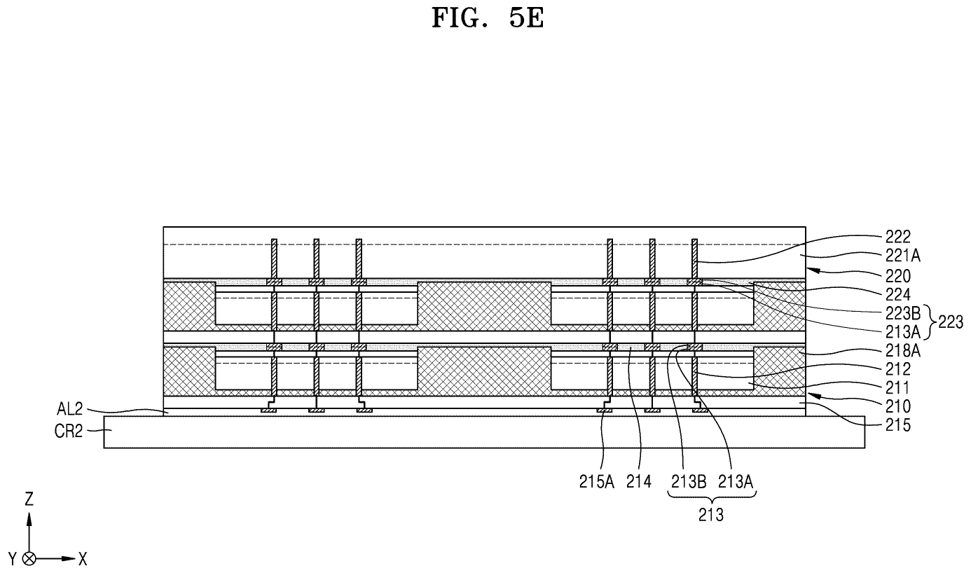

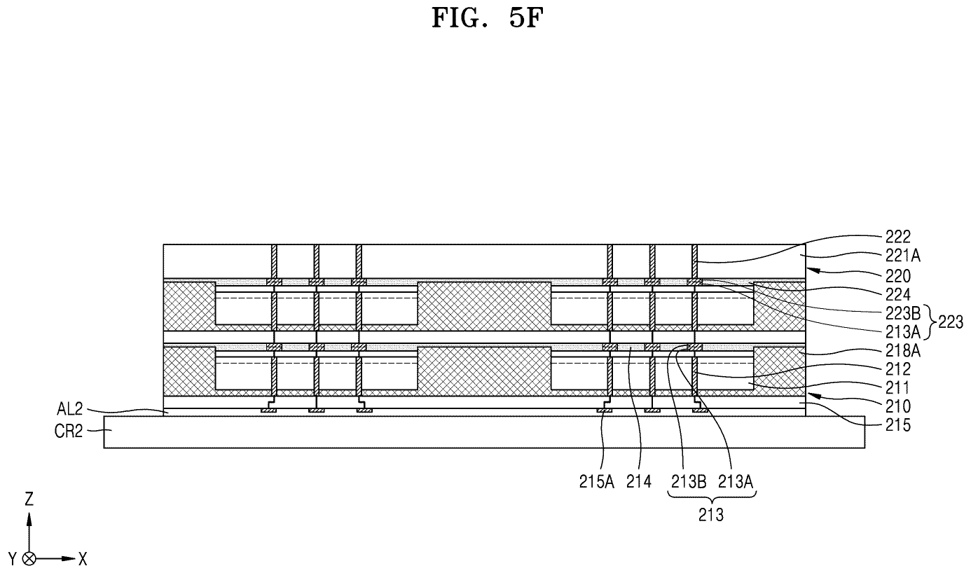

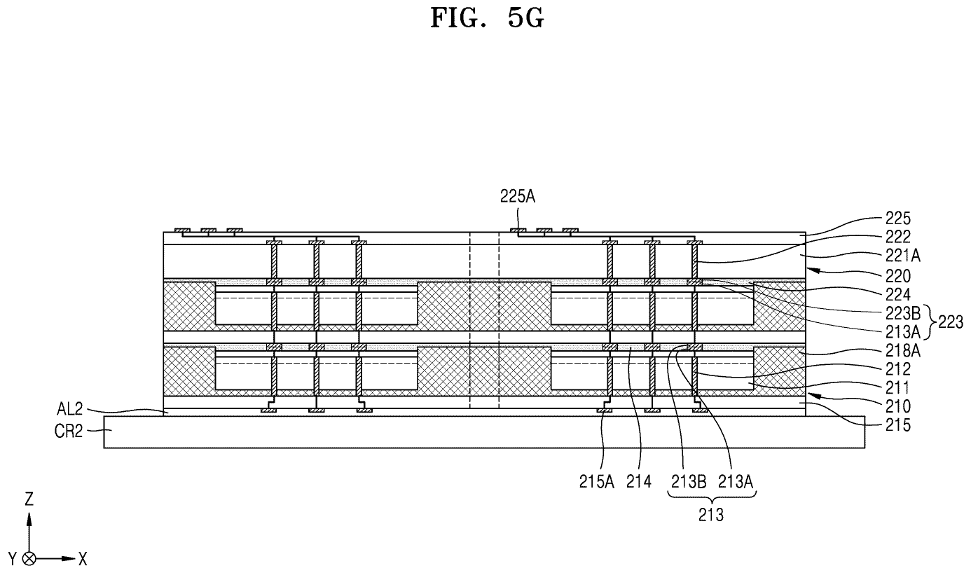

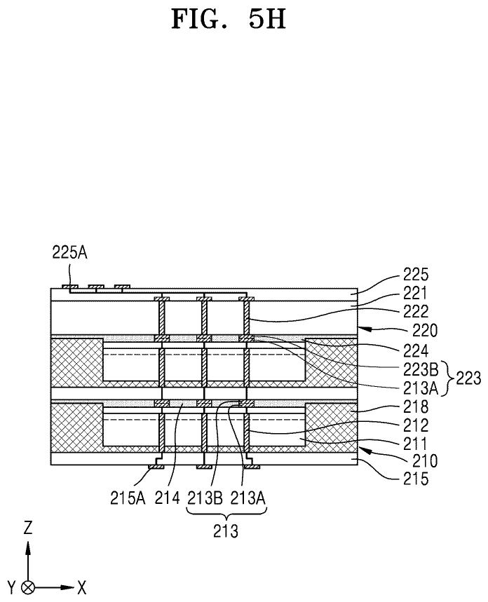

FIGS. 5A through 5H show cross-sectional views sequentially illustrating a process of manufacturing the semiconductor package 1, according to an embodiment. Descriptions not separately given may be substantially the same as the descriptions given above.

Referring to FIG. 5A, a first adhesion layer AL1 may be arranged on a first carrier CR1, and a second semiconductor substrate 221A may be arranged on the first carrier CR1. For example, the second semiconductor substrate 221A may, in a wafer state, be processed into a wafer level package. The second semiconductor substrate 221A may represent a portion of ae wafer. A plurality of second through electrodes 222 may be formed on the second semiconductor substrate 221A, and the separately manufactured first semiconductor substrate 211 may be arranged to correspond to the second semiconductor substrate 221A. For example, the first semiconductor substrate 211 may be mounted on the second semiconductor substrate 221A by using the direct bonding process.

Referring to FIGS. 5B and 5C, a first encapsulation member 218A may be formed in the process result of FIG. 5A. Next, a chemical mechanical polishing process may be performed on the first encapsulation member 218A. In some an embodiment, portions of the plurality of first through electrodes 212 may be removed while the first encapsulation member 218A is polished. The first redistribution layer 215 may be formed on the first encapsulation member 218A and the plurality of first through electrodes 212 by using a first redistribution process.

Referring to FIG. 5D, another first semiconductor substrate 211 may be arranged to correspond to the first redistribution layer 215 of the process result of FIG. 5C. The processes of FIGS. 5A through 5C may be performed in the similar manner to form the first encapsulation member 218A and the first redistribution layer 215.

Referring to FIG. 5E, the first carrier CR1 and the first adhesion layer AL1 may be removed, and the process result of FIG. 5D may be vertically inverted to be arranged on a second carrier CR2. A second adhesion layer AL2 may be arranged between the process result of FIG. 5D and the second carrier CR2 on the second carrier CR2.

Referring to FIG. 5F, a rear surface process may be performed on the second semiconductor substrate 221A in FIG. 5E, and portions of the second semiconductor substrate 221A and the plurality of second through electrodes 222 may be removed. The rear surface process may include a grinding process or a chemical mechanical polishing process. By using the rear surface process, one end of each of the plurality of second through electrodes 222 may be exposed on the second semiconductor substrate 221A.

Referring to FIG. 5G, the second redistribution layer 225 may be formed on an upper surface of the second semiconductor substrate 221A on which the rear surface process has been performed. The second redistribution layer 225 may be formed by using a second redistribution process.

Referring to FIG. 5H, the process result of FIG. 5G may be individualized, and accordingly, a first semiconductor structure, in which the first semiconductor device 210 and the second semiconductor device 220 are stacked, may be formed. The process result of FIG. 5G may be individualized, for example, by sawing the process result along scribe lanes indicated by dashed lines in FIG. 5G.

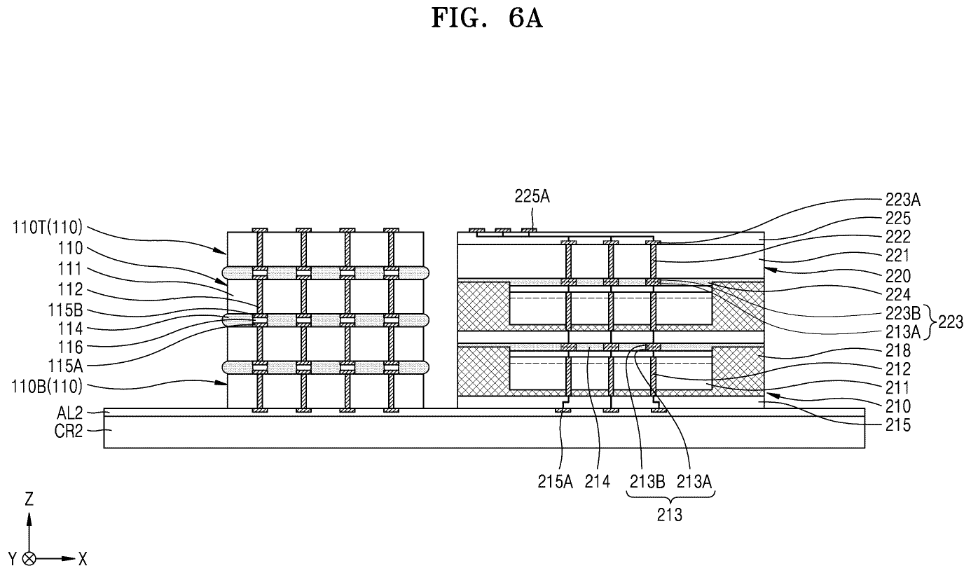

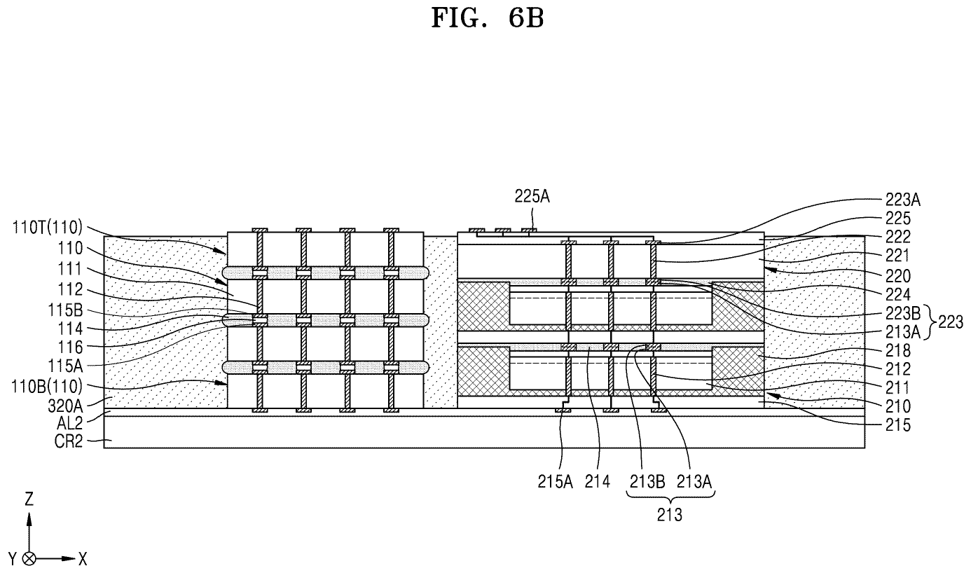

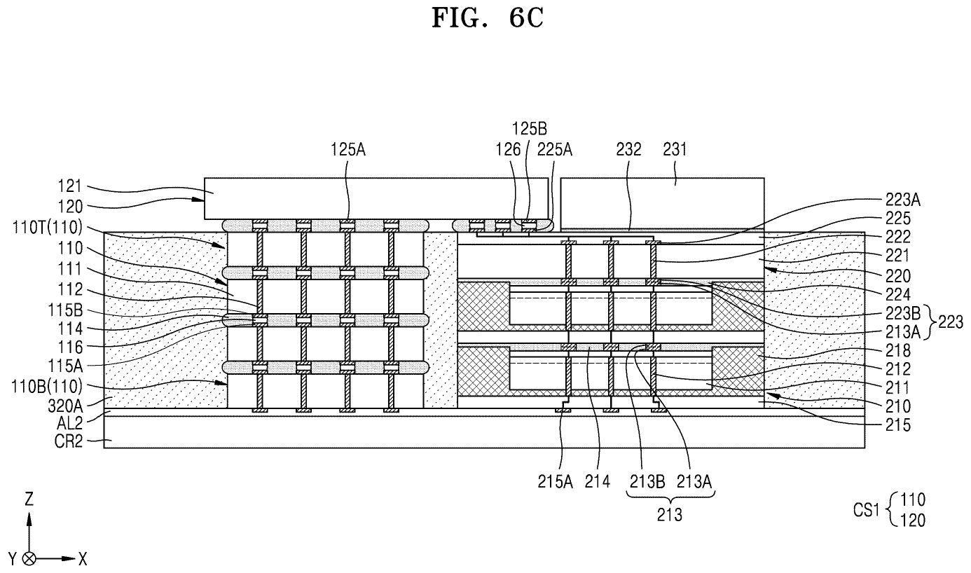

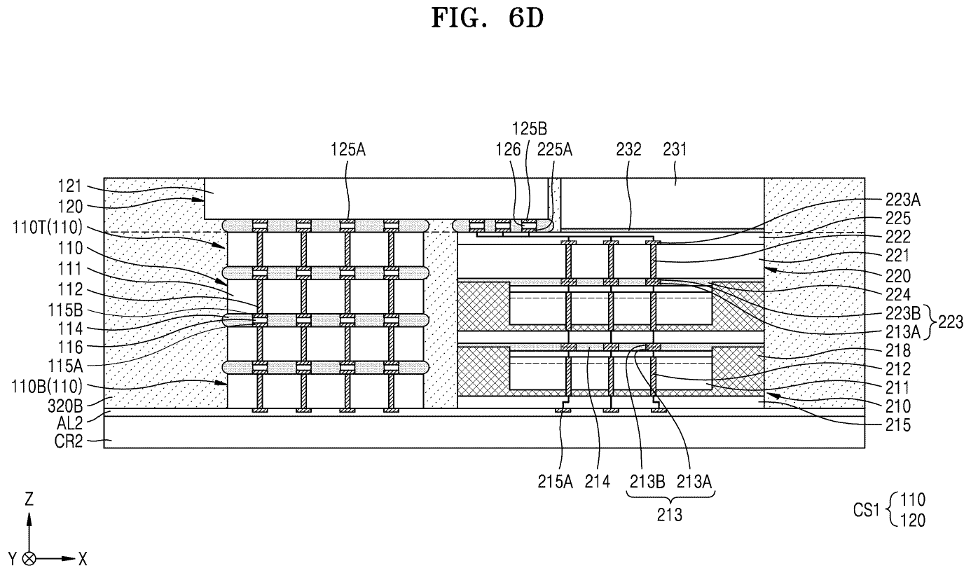

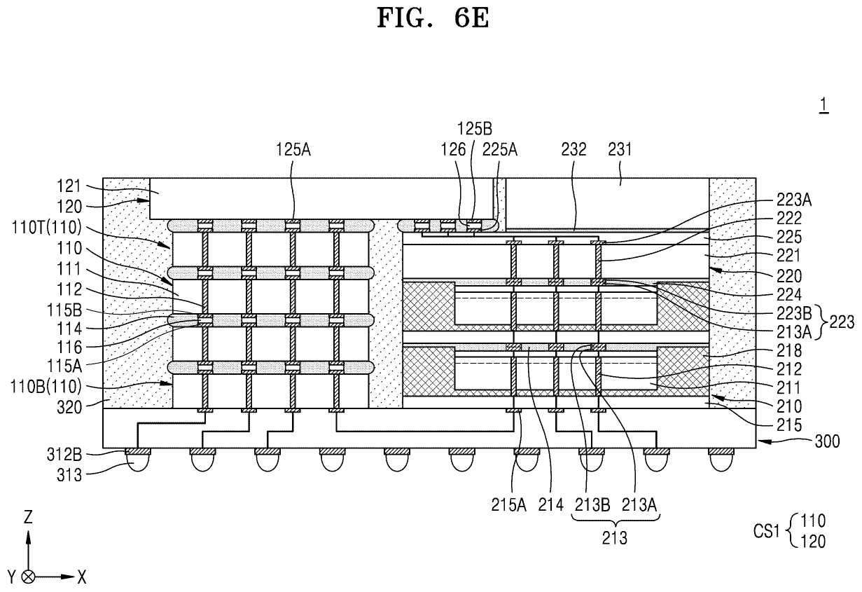

FIGS. 6A through 6E show cross-sectional views sequentially illustrating a process of manufacturing the semiconductor package 1, according to an embodiment. Descriptions not separately given may be substantially the same as the descriptions given above.

Referring to FIG. 6A, the stacked plurality of first core chips 110 and the first semiconductor structure in FIG. 5H may be arranged apart from each other, on a third carrier CR3 and a third adhesion layer CR3 provided on the third carrier CR3.

Referring to FIG. 6B, the stacked plurality of first core chips 110 and a first package encapsulation member 320A surrounding the first semiconductor structure of FIG. 5H may be formed. The first package encapsulation member 320A may be formed at a vertical level lower than the upper surface of the uppermost first core chip 110T and the upper surface of the second semiconductor device 220.

Referring to FIG. 6C, the stacked plurality of first core chips 110 and the first buffer chip 120 may be arranged on the first semiconductor structure, and the heat dissipation structure 231 apart from the first buffer chip 120 in a lateral direction may be arranged on the second semiconductor device 220. For example, the first buffer chip 120 may be mounted on the stacked plurality of first core chips 110 and the first semiconductor structure by using a thermo-compression bonding process.

Referring to FIG. 6D, a second package encapsulation member, which surrounds the stacked plurality of first core chips 110 and the rest of the first semiconductor structure, and surrounds side surfaces of the first buffer chip 120 and the heat dissipation structure 231, may be additionally formed. The second package encapsulation member may be formed on the first package encapsulation member 320A formed in the process of FIG. 6B, and the first package encapsulation member 320A and the second package encapsulation member may be integrated into one body to form a package encapsulation member 320B.

Referring to FIG. 6E, after the second carrier CR2 is removed from the process result of FIG. 6D, the package substrate 300 extending onto the lower surface of the first core chip 110 and the lower surface of the first semiconductor device 210 may be formed. For example, in the process result of FIG. 6D from which the second carrier CR2 has been removed, the package substrate 300, which is a third redistribution structure, may be formed by performing a third redistribution process on the lower surface of the first core chip 110 and the lower surface of the first semiconductor device 210.

While the inventive concept has been particularly shown and described with reference to illustrative examples thereof, it will be understood by those of ordinary skill in the pertinent art that various changes in form and details may be made therein without departing from the spirit and scope of the present disclosure as bounded by the following claims.

What is claimed is:

1. A semiconductor package comprising:
a package substrate;
a first semiconductor device arranged on the package substrate;
a second semiconductor device arranged on the first semiconductor device;
a heat dissipation structure arranged on the second semiconductor device; and
at least one first chip stack including a plurality of first core chips and a first buffer chip, wherein the plurality of first core chips are apart from the first semiconductor device in a lateral direction and sequentially stacked on the package substrate,
wherein the first buffer chip is arranged on the second semiconductor device and the at least one first chip stack,
wherein the heat dissipation structure is arranged apart from the first buffer chip in the lateral direction, and
wherein the plurality of first core chips comprise a plurality of first core through electrodes configured to penetrate at least a portion of each of the plurality of first core chips.

2. The semiconductor package of claim 1, wherein
the plurality of first core chips are electrically connected to the first buffer chip,
a connection pad is arranged between the second semiconductor device and the first buffer chip, and
the second semiconductor device is electrically connected to the first buffer chip via the connection pad.

3. The semiconductor package of claim 1,
further comprising a package encapsulation member surrounding the at least one first chip stack, the first semiconductor device, the second semiconductor device, and the heat dissipation structure,
wherein an upper surface of the first buffer chip, an upper surface of the heat dissipation structure, and an upper surface of the package encapsulation member are coplanar with each other.

4. The semiconductor package of claim 1, wherein
the first semiconductor device comprises the plurality of first through electrodes, and
the second semiconductor device comprises a plurality of second through electrodes.

5. The semiconductor package of claim 1,
wherein the first buffer chip comprises a first physical layer,
wherein the second semiconductor device comprises a second physical layer,
wherein the first physical layer is arranged closer to a first side surface of the first buffer chip than a second side surface of the first buffer chip,
wherein the first side surface of the first buffer chip faces the heat dissipation structure, and the second side surface is opposite to the first side surface,
wherein the second physical layer is arranged closer to a third side surface of the second semiconductor device than a fourth side surface of the second semiconductor device, and
wherein the fourth side surface is opposite to the third side surface, and the third side surface faces side surfaces of the plurality of first core chips.

6. The semiconductor package of claim 1,
further comprising at least one second core chip stacked between the package substrate and the first semiconductor device.

7. The semiconductor package of claim 1,
wherein, based on an uppermost first core chip at an uppermost end among the plurality of first core chips, a protruding distance of a first side surface of the first buffer chip in one lateral direction is greater than a protruding distance of a second side surface of the first buffer chip, which is opposite to the first side surface, in the one lateral direction, and
wherein the first side surface of the first buffer chip faces the heat dissipation structure.

8. The semiconductor package of claim 1, wherein
the first semiconductor device comprises a memory chip, and
the second semiconductor device comprises a logic chip.

9. The semiconductor package of claim 1, wherein
the first semiconductor device comprises a first semiconductor chip, a plurality of first through electrodes configured to penetrate at least a portion of the first semiconductor chip, a first encapsulation member surrounding the first semiconductor chip, and a first redistribution structure facing the first semiconductor chip,
wherein the plurality of first through electrodes are electrically connected to the first redistribution structure,
wherein the first semiconductor chip comprises a first active surface, and
wherein the first active surface is provided closer to an upper surface of the first semiconductor chip than a lower surface of the first semiconductor chip.

10. The semiconductor package of claim 1, wherein
a bonding pad is arranged between the first semiconductor device and the second semiconductor device, and the bonding pad is directly bonded.

11. The semiconductor package of claim 1, wherein
the second semiconductor device comprises a second semiconductor chip, a plurality of second through electrodes configured to penetrate at least a portion of the second semiconductor chip, and a second redistribution structure arranged on one surface of the second semiconductor chip and electrically connected to the plurality of second through electrodes.

12. The semiconductor package of claim 1, wherein
a bonding pad is arranged between the plurality of first core chips, and the plurality of first core chips are directly bonded to each other.

13. The semiconductor package of claim 1,
further comprising a filler structure,
wherein the filler structure comprises an upper redistribution layer, a lower redistribution layer facing the upper redistribution layer, a plurality of conductive fillers provided between the upper redistribution layer and the lower redistribution layer, and a third encapsulation member surrounding the plurality of conductive fillers between the upper redistribution layer and the lower redistribution layer, and
wherein the filler structure is arranged on the second semiconductor device, a connection pad is provided between the filler structure and the first buffer chip, and the filler structure is electrically connected to the first buffer chip via the connection pad.

14. The semiconductor package of claim 1,
further comprising a filler structure,
wherein the filler structure comprises an upper redistribution layer, a lower redistribution layer facing the upper redistribution layer, a plurality of conductive fillers provided between the upper redistribution layer and the lower redistribution layer, and a third encapsulation member surrounding the plurality of conductive fillers between the upper redistribution layer and the lower redistribution layer, and
wherein the filler structure is provided between the first semiconductor device and the second semiconductor device, the upper redistribution layer is electrically connected to the second semiconductor device, and the lower redistribution layer is electrically connected to the first semiconductor device.

15. The semiconductor package of claim 1,
further comprising a second chip stack including a plurality of second core chips sequentially stacked on the package substrate and a second buffer chip arranged on the second semiconductor device and the plurality of second core chips,
wherein the second chip stack is apart from the second semiconductor device in a lateral direction,
the second buffer chip is arranged to extend on and beyond the second semiconductor device, and
the heat dissipation structure is apart from the second buffer chip in the lateral direction.

16. A semiconductor package comprising:
a package substrate;
a first semiconductor device arranged on the package substrate and including a memory chip;
a second semiconductor device arranged on the first semiconductor device and including a logic chip;
a heat dissipation structure arranged on the second semiconductor device;
at least one first chip stack including a plurality of first core chips and a first buffer chip, wherein the plurality of first core chips are apart from the first semiconductor device in a lateral direction and sequentially stacked on the package substrate and the first buffer chip is arranged on the second semiconductor device and the plurality of first core chips; and
a package encapsulation member surrounding the at least one first chip stack, the first semiconductor device, the second semiconductor device, and the heat dissipation structure,
wherein the heat dissipation structure is arranged apart from the first buffer chip in the lateral direction,
wherein the plurality of first core chips comprise a plurality of first core through electrodes configured to penetrate at least a portion of each of the plurality of first core chips, the first semiconductor device comprises a plurality of first through electrodes, and the second semiconductor device comprises a plurality of second through electrodes,
wherein a portion of the first buffer chip overlaps a portion of the second semiconductor device in a vertical direction, and
wherein an upper surface of the first buffer chip, an upper surface of the heat dissipation structure, and an upper surface of the package encapsulation member are coplanar with each other.

17. The semiconductor package of claim 16,
wherein the first buffer chip comprises a first physical layer,
wherein the second semiconductor device comprises a second physical layer,
wherein the first physical layer is arranged closer to a first side surface of the first buffer chip than a second side surface of the first buffer chip,
wherein the second physical layer is arranged closer to a third side surface of the second semiconductor device than a fourth side surface of the second semiconductor device,
wherein the first side surface of the first buffer chip faces the heat dissipation structure, and the second side surface is opposite to the first side surface, and
wherein the fourth side surface is opposite to the third side surface, and the third side surface faces side surfaces of the plurality of first core chips.

18. The semiconductor package of claim 16, wherein the package substrate comprises a redistribution structure.

19. The semiconductor package of claim 16, wherein
a vertical level of an upper surface of the second semiconductor device is substantially the same as a vertical level of an upper surface of an uppermost first core chip farthest apart from the package substrate among the plurality of first core chips.

20. A semiconductor package comprising:
a package substrate;
a first semiconductor device arranged on the package substrate and including a memory chip;
a second semiconductor device arranged on the first semiconductor device and including a logic chip;
a heat dissipation structure arranged on the second semiconductor device;
at least one first chip stack including a plurality of first core chips and a first buffer chip, wherein the plurality of first core chips are apart from the first semiconductor device in a lateral direction and sequentially stacked on the package substrate and the first buffer chip is arranged on the second semiconductor device and the plurality of first core chips; and
a package encapsulation member surrounding the at least one first chip stack, the first semiconductor device, the second semiconductor device, and the heat dissipation structure,
wherein the heat dissipation structure is arranged apart from the first buffer chip in the lateral direction,
wherein the plurality of first core chips comprise a plurality of first core through electrodes configured to penetrate at least a portion of each of the plurality of first core chips, the first semiconductor device comprises a plurality of first through electrodes, and the second semiconductor device comprises a plurality of second through electrodes,
wherein a portion of the first buffer chip overlaps a portion of the second semiconductor device in a vertical direction,
wherein an upper surface of the first buffer chip, an upper surface of the heat dissipation structure, and an upper surface of the package encapsulation member are coplanar with each other,
wherein the first buffer chip comprises a first physical layer,
wherein the second semiconductor device comprises a second physical layer,
wherein the first physical layer is arranged closer to a first side surface of the first buffer chip than a second side surface of the first buffer chip,
wherein the second physical layer is arranged closer to a third side surface of the second semiconductor device than a fourth side surface of the second semiconductor device,
wherein the first side surface of the first buffer chip faces the heat dissipation structure, the second side surface is opposite to the first side surface, the fourth side surface is opposite to the third side surface, and the third side surface faces side surfaces of the plurality of first core chips,
wherein a vertical level of an upper surface of the second semiconductor device is substantially the same as a vertical level of an upper surface of an uppermost first core chip farthest apart from the package substrate among the plurality of first core chips,
wherein the first semiconductor device comprises a first semiconductor chip, the plurality of first through electrodes configured to penetrate at least a portion of the first semiconductor chip, a first encapsulation member surrounding the first semiconductor chip, and a first redistribution structure facing the first semiconductor chip,
wherein the plurality of first through electrodes are electrically connected to the first redistribution structure, the first semiconductor chip comprises a first active surface, and the first active surface is provided closer to an upper surface of the first semiconductor chip than a lower surface of the first semiconductor chip, and
wherein the second semiconductor device comprises a second semiconductor chip, a plurality of second through electrodes configured to penetrate at least a portion of the second semiconductor chip, and a second redistribution structure arranged on one surface of the second semiconductor chip and electrically connected to the plurality of second through electrodes.
